(19) United States
(12) Patent Application Publication
(10) Pub. No.: US 2009/0057679 A1
(43) Pub. Date: Mar. 5, 2009

(54) THIN FILM TRANSISTOR AND MANUFACTURING METHOD THEREOF

(75) Inventors: Chin-Chuan Lai, Taoyuan County (TW); Wen-Chun Yeh, Taoyuan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: CHUNGHWA PICTURE TUBES, LTD., Taipei (TW)

(21) Appl. No.: 12/168,163

(22) Filed: Jul. 7, 2008

(30) Foreign Application Priority Data
Sep. 3, 2007 (TW) 96132747

(51) Int. Cl. H01L 29/04; H01L 21/336

(52) U.S. Cl. 257/66; 438/163; 257/E29.003; 257/E21.413

(57) ABSTRACT

A manufacturing method of a TFT is provided. A polysilicon island, a gate insulating layer and a gate are sequentially formed on a substrate. LDD regions are formed in the polysilicon island below two sides of the gate, while the polysilicon island below the gate is a channel region. A metal oxidation process is performed to form a gate oxidation layer on the gate. A source and a drain are formed in the polysilicon island below two sides of the gate oxidation layer. A dielectric layer is formed on the gate insulating layer. Portions of the dielectric layer and the gate insulating layer are removed to expose a portion of the source and drain, and a patterned dielectric layer and a patterned gate insulating layer are formed. A source and a drain conductive layers electrically respectively connected to the source and the drain are formed on the patterned dielectric layer.

### CROSS-REFERENCE TO RELATED APPLICATION

This application claims the priority benefit of Taiwan application serial no. 96132747, filed on Sep. 3, 2007. The entirety of the above-mentioned patent application is hereby incorporated by reference herein and made a part of specification.

### BACKGROUND OF THE INVENTION

1. Field of the Invention

The present invention relates to a semiconductor device and a manufacturing method thereof, and more particularly, to a thin film transistor (TFT) and a manufacturing method thereof.

2. Description of Related Art

With advancement of technologies, digital image devices have been widely developed and applied in daily lives. One of the most common digital image devices is liquid crystal displays (LCDs). In active matrix LCDs, driving devices of the active matrix LCDs include TFTs, diodes, and so on. On the other hand, based on materials of channel regions of the TFTs, the TFTs may be classified into amorphous silicon (a-Si) TFTs and polysilicon TFTs. By virtue of relatively low power consumption and great electron mobility in comparison with the a-Si TFTs, the polysilicon TFTs have drawn more attention in the industry.

FIGS. 1A through 1E schematically illustrate a manufacturing method of a polysilicon TFT disclosed in U.S. Pat. No. 6,452,241. Referring to FIG. 1A, the conventional manufacturing method of the polysilicon TFT includes the following steps. First, a polysilicon island 120 is formed on a substrate 110.

Referring to FIG. 1B, a patterned photoresist layer 210 is formed on the polysilicon island 120. Next, an ion implantation process S110 is performed with use of the patterned photoresist layer 210 as a mask, so as to form a source 122a and a drain 122b in the polysilicon island 120. Here, a channel region 124 is located between the source 122a and the drain 122b. Thereafter, the patterned photoresist layer 210 is removed.

Referring to FIG. 1C, a gate insulating layer 130 is formed on the substrate 110 to cover the polysilicon island 120. A gate 140 is then formed on the gate insulating layer 130 on the polysilicon island 120. Next, a lightly doped drain (LDD) ion implantation process S120 is performed with use of the gate 140 as the mask, so as to form LDDs region 126a, 126b in the polysilicon island 120 below two sides of the gate 140. Here, the LDDs region 126a, 126b are located between the source and drain 122a, 122b and the channel region 124.

Referring to FIG. 1D, a dielectric layer 150 is formed on the gate insulating layer 130 to cover the gate 140.

Referring to FIG. 1E, a patterning process is performed on the dielectric layer 150 and the gate insulating layer 130, so as to expose a portion of the source 122a and the drain 122b and to form a patterned dielectric layer 150a and a patterned gate insulating layer 130a. After that, a source conductive layer 160a and a drain conductive layer 160b are formed on the patterned dielectric layer 150a. Here, the source conductive layer 160a and the drain conductive layer 160b are electrically connected to the source 122a and the drain 122b, respectively.

A patterned photoresist layer 210 should be formed for constructing the LDD regions 126a, 126b, and an additional photo mask is required during the formation of the patterned photoresist layer 210. The manufacturing method according to the related art necessitates more photo masks, and thus the manufacturing costs are increased. On the other hand, due to alignment errors occurring among the photo masks, the gate 140 is not likely to be formed at a proper position in most cases. Thereby, the LDD regions 126a, 126b at respective sides of the channel region 124 may be asymmetrical, thus resulting in unfavorable electrical performance.

### SUMMARY OF THE INVENTION

In view of the above, the present invention is directed to a manufacturing method of a TFT for reducing the number of required photo masks.

The present invention is further directed to a TFT having relatively satisfactory electrical performance.

The invention provides a manufacturing method of a TFT. The manufacturing method includes the following steps. A polysilicon island is formed on a substrate. A gate insulating layer is formed on the substrate and covers the polysilicon island. A gate is formed on the gate insulating layer on the polysilicon island. A lightly doped ion implantation process is then implemented for forming LDD regions in the polysilicon island below two sides of the gate, while the polysilicon island right below the gate is a channel region. Next, a metal oxidation process is performed to form a gate oxidation layer on the gate. Thereafter, an ion implantation process is performed to form a source and a drain in the polysilicon island below two sides of the gate oxidation layer. Here, the LDD regions are located between the source/drain and the channel region. After that, a dielectric layer is formed on the gate insulating layer, so as to cover the gate oxidation layer. A portion of the dielectric layer and a portion of the gate insulating layer are then removed to expose a portion of the source and the drain, and a patterned dielectric layer and a patterned gate insulating layer are formed. Next, a source conductive layer and a drain conductive layer are formed on the patterned dielectric layer, and the source and the drain conductive layers are electrically connected to the source and the drain, respectively.

According to an embodiment of the present invention, the metal oxidation process is an anode oxidation process.

According to an embodiment of the present invention, a voltage applied in the anode oxidation process ranges from 5 volts to 200 volts.

According to an embodiment of the present invention, a time period of applying the voltage ranges from 10 minutes to 120 minutes.

According to an embodiment of the present invention, a material of the gate includes aluminum, tantalum, titanium, or an alloy thereof.

According to an embodiment of the present invention, the metal oxidation process is a thermal oxidation process.

According to an embodiment of the present invention, a temperature of the thermal oxidation process ranges from 350° C. to 550° C.

According to an embodiment of the present invention, a time period of the thermal oxidation process ranges from 2 hours to 24 hours.

According to an embodiment of the present invention, a material of the gate includes copper, aluminum, chromium, molybdenum, tantalum, titanium, or an alloy thereof.

According to an embodiment of the present invention, the manufacturing method of the TFT further includes forming a buffer layer on the substrate before the polysilicon island is formed.

The present invention further provides a TFT including a substrate, a polysilicon island, a patterned gate insulating layer, a gate, a gate oxidation layer, LDD regions, a source and a drain, a patterned dielectric layer, and a source conductive layer and a drain conductive layer. The polysilicon island is disposed on the substrate. The patterned gate insulating layer is disposed on the substrate and exposes a portion of the polysilicon island. The gate is disposed on the patterned gate insulating layer on the polysilicon island, while the gate oxidation layer is disposed on the patterned gate insulating layer and covers the gate. The LDD regions are disposed in the polysilicon island below two sides of the gate, whereas the polysilicon island disposed right below the gate is a channel region. The source and the drain are disposed in the polysilicon island below two sides of the gate oxidation layer. The patterned gate insulating layer exposes a portion of the source and the drain. The LDD regions are located between the source/drain and the channel region. The patterned dielectric layer is disposed on the patterned gate insulating layer and exposes the source and the drain exposed by the patterned gate insulating layer. The source and the drain conductive layers are disposed on the patterned dielectric layer. Here, the source and the drain conductive layers are electrically connected to the source and the drain, respectively.

According to an embodiment of the present invention, the LDD regions are located below the gate oxidation layer, and an edge of the gate oxidation layer is aligned to an edge of the LDD regions.

According to an embodiment of the present invention, a thickness of the gate oxidation layer ranges from 100 nm to 1000 nm.

According to an embodiment of the present invention, the thickness of the gate oxidation layer ranges from 400 nm to 600 nm.

According to an embodiment of the present invention, a thickness of the gate ranges from 100 nm to 3000 nm.

According to an embodiment of the present invention, a material of the gate includes copper, aluminum, chromium, molybdenum, tantalum, titanium, or an alloy thereof.

According to an embodiment of the present invention, the TFT further includes a buffer layer disposed between the polysilicon island and the substrate.

Based on the above, the gate and the gate oxidation layer formed by the metal oxidation process are employed as masks to implement the ion implantation process in the present invention, such that the source, the drain and the LDD regions are formed. As a result, compared with the manufacturing method requiring two photo masks according to the related art, the manufacturing method of the TFT according to the present invention merely requires one photo mask for forming the source, the drain and the LDD regions.

In order to the make the aforementioned and other objects, features and advantages of the present invention comprehensible, embodiments accompanied with figures are described in detail below.

### BRIEF DESCRIPTION OF THE DRAWINGS

FIGS. 1A through 1E schematically illustrate a manufacturing method of a polysilicon TFT disclosed in U.S. Pat. No. 6,452,241.

FIGS. 2A through 2F schematically illustrate a manufacturing method of a TFT according to an embodiment of the present invention.

### DESCRIPTION OF EMBODIMENTS

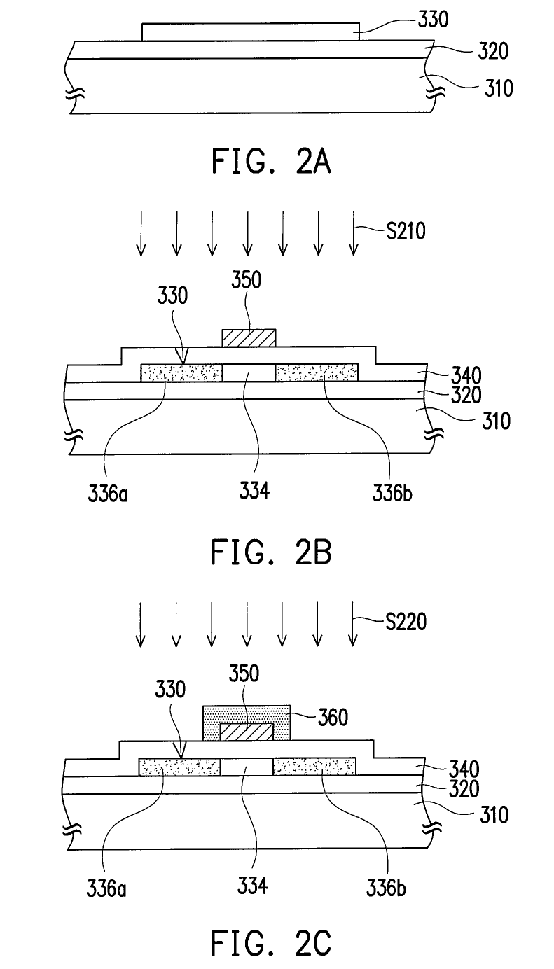

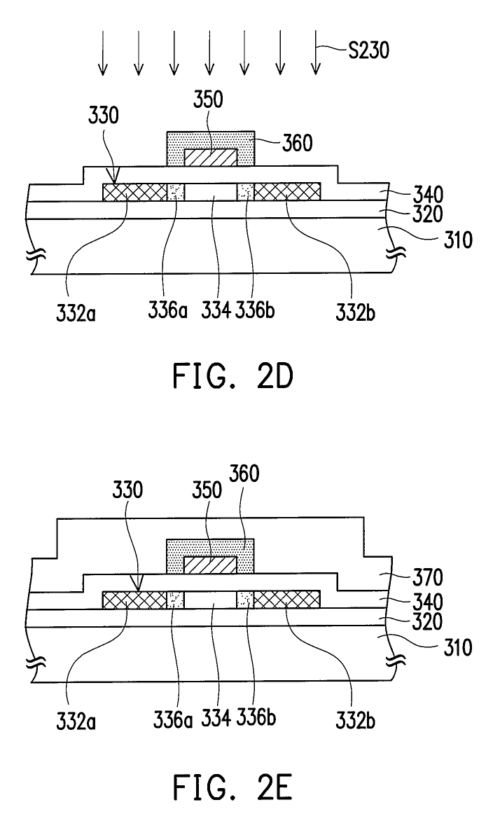

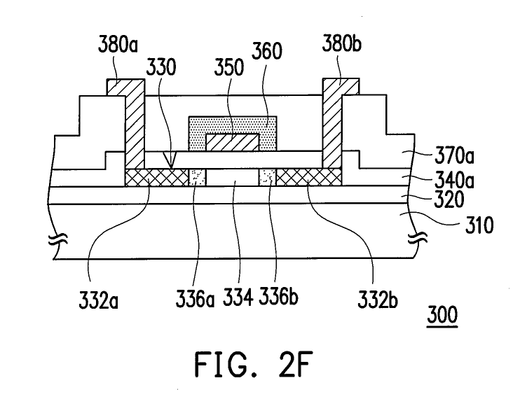

FIGS. 2A through 2F schematically illustrate a manufacturing method of a TFT according to an embodiment of the present invention. Referring to FIG. 2A, the manufacturing method of the TFT according to the present embodiment includes the steps as follows. First, a polysilicon island 330 is formed on a substrate 310. More particularly, the step of forming the polysilicon island 330 includes first forming an a-Si layer (not shown) on the substrate 310 by implementing a chemical vapor deposition (CVD) process or a plasma enhanced chemical vapor deposition (PECVD) process, for example. Next, a laser annealing process is preformed on the a-Si layer to transform the a-Si layer into a polysilicon layer. A photolithography process and an etching process are then performed on the polysilicon layer to form the polysilicon island 330 on the substrate 310.

On the other hand, in order to prevent metal ions in the substrate 310 from diffusing into the polysilicon island 330, a buffer layer 320 may also be formed on the substrate 310 before the a-Si layer is constructed. The buffer layer 320 may be formed by performing a low pressure chemical vapor deposition (LPCVD) process or the PECVD process, for example.

As shown in FIG. 2B, a gate insulating layer 340 is formed on the substrate 310 and covers the polysilicon island 330. In detail, the gate insulating layer 340 may be formed by implementing the PECVD process. Additionally, in order to adjust electrical properties of the polysilicon island 330, a channel doping process may also be performed on the polysilicon island 330 after the formation of the gate insulating layer 340.

Referring to FIG. 2B, a gate 350 is formed on the gate insulating layer 340 on the polysilicon island 330. More specifically, the gate 350 may be constructed by performing a sputtering process or a physical vapor deposition (PVD) process on the gate insulating layer 340, such that a gate material layer (not shown) is formed. Thereafter, the photolithography process and the etching process are performed on the gate material layer, so as to form the gate 350.

Referring to FIG. 2B, a lightly doped ion implantation process S210 is then implemented for forming LDD regions 336a, 336b in the polysilicon island 330 below two sides of the gate 350, while the polysilicon island 330 right below the gate 350 is a channel region 334. Besides, the ions implanted through the lightly doped ion implantation process S210 may be N-type dopants, and the N-type dopants may be phosphorous ions.

Next, with reference to FIG. 2C, a metal oxidation process S220 is implemented to form a gate oxidation layer 360 on the gate 350. In particular, the metal oxidation process S220 may be an anode oxidation process or a thermal oxidation process. As regards the anode oxidation process, a voltage applied therein may range from 5 volts to 200 volts, while a time period of applying the voltage is between 10 minutes and 120 minutes. In addition, a material of the gate 350 employed in the anode oxidation process may be aluminum, tantalum, titanium, or an alloy thereof.

On the contrary, a temperature at which the thermal oxidation process is performed may range from 350° C. to 550° C., and a time period during which the thermal oxidation process is implemented is between 2 hours and 24 hours. In addition, a material of the gate 350 employed in the thermal oxidation process may be copper, aluminum, chromium, molybdenum, tantalum, titanium, or an alloy thereof.

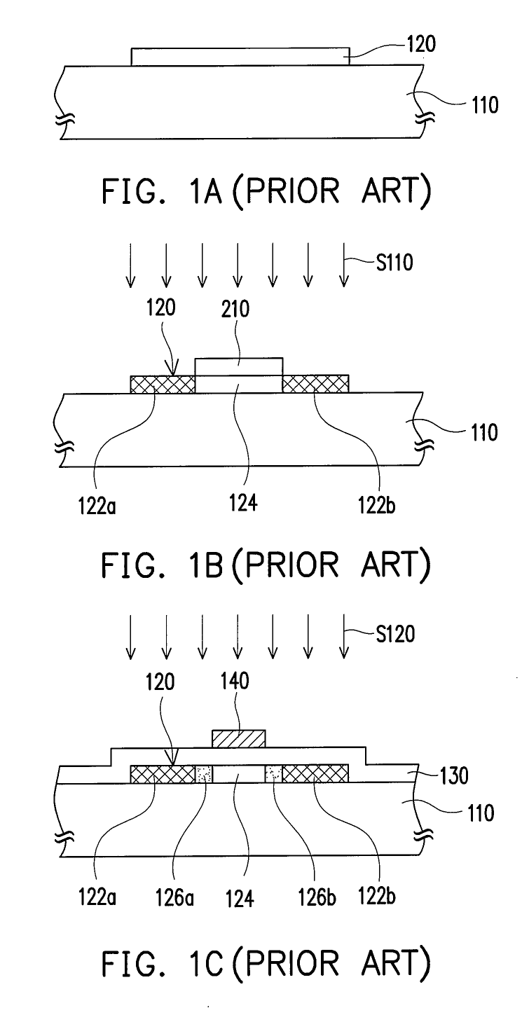

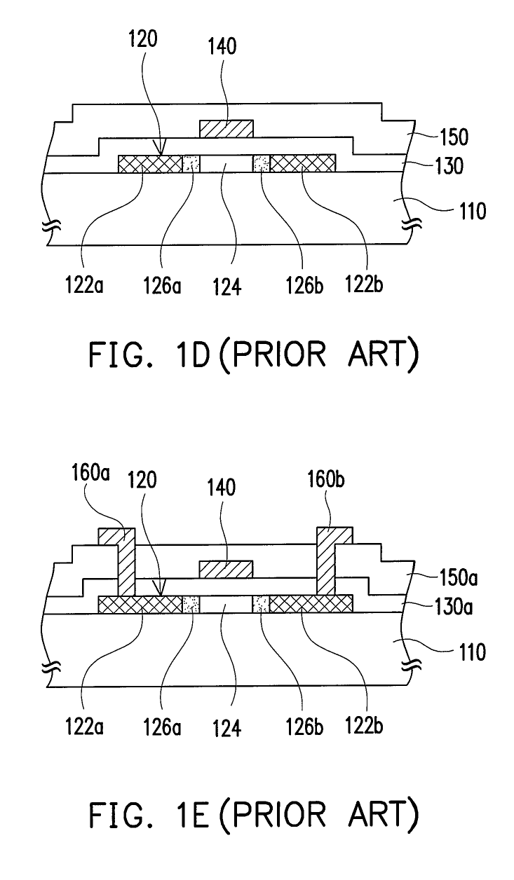

Thereafter, referring to FIG. 2D, an ion implantation process S230 is implemented to form a source 332a and a drain 332b in the polysilicon island 330 below two sides of the gate oxidation layer 360. Here, the LDD regions 336a, 336b are located between the source/drain 332a/332b and the channel region 334. Additionally, the ions implanted by the ion implantation process S230 may be the N-type dopants, and the N-type dopants may be the phosphorous ions. More specifically, the gate oxidation layer 360 is adopted as a mask in the ion implantation process S230. Hence, an edge of the source and the drain 332a, 332b is aligned to an edge of the gate oxidation layer 360, and the LDD regions 336a, 336b are located between the source/drain 332a/332b and the channel region 334. That is to say, compared with the conventional manufacturing method requiring two photo masks for forming the LDD regions 126a, 126b and the source and drain 122a, 122b (as shown in FIGS. 1B-1C), the manufacturing method of the TFT according to the present embodiment merely requires one photo mask to form the source/drain 332a/332b and the LDD regions 336a, 336b. Moreover, since the source and the drain 332a, 332b are formed by performing the ion implantation process S230 thereon with use of the gate oxidation layer 360 as the mask, the LDD regions 336a, 336b at respective sides of the channel region 334 are relatively symmetrical.

Next, referring to FIG. 2E, a dielectric layer 370 is formed on the gate insulating layer 340 to cover the gate 350 and the gate oxidation layer 360. In particular, the dielectric layer 370 may be formed by implementing the CVD process.

Next, with reference to FIG. 2F, a portion of the dielectric layer 370 and a portion of the gate insulating layer 340 are removed to expose a portion of the source and the drain 332a, 332b, and a patterned dielectric layer 370a and a patterned gate insulating layer 340a are then formed. The portions of the dielectric layer 370 and the gate insulating layer 340 may be removed by implementing the photolithography process and the etching process. After that, a source conductive layer 380a and a drain conductive layer 380b are formed on the patterned dielectric layer 370a. Here, the source and the drain conductive layers 380a, 380b are electrically connected to the source and the drain 332a and 332b, respectively. Specifically, the source conductive layers 380a and the drain conductive layer 380b may be constructed by first forming a conductive material layer on the patterned dielectric layer 370a through the sputtering process or the PVD process. The photolithography process and the etching process are then performed on the conductive material layer, so as to form the source and the drain conductive layers 380a, 380b. A structure of the TFT 300 will be discussed in detail below.

Referring to FIG. 2F, the TFT 300 of the present embodiment includes a substrate 310, a polysilicon island 330, a patterned gate insulating layer 340a, a gate 350, a gate oxidation layer 360, LDD regions 336a, 336b, a source 332a and a drain 332b, a patterned dielectric layer 370a, and a source conductive layer 380a and a drain conductive layer 380b. Here, the polysilicon island 330 is disposed on the substrate 310. The substrate 310 may be a glass substrate, a quartz substrate, or a plastic substrate. Besides, a buffer layer 320 may be further formed in the TFT 300, so as to prevent the metal ions in the substrate 310 from diffusing into the polysilicon island 330. The buffer layer 320 is disposed between the substrate 310 and the polysilicon island 330, and may be made of single-layered silicon oxide or double-layered silicon oxide/silicon nitride.

The patterned gate insulating layer 340a is disposed on the buffer layer 320 and exposes a portion of the polysilicon island 330. Here, a material of the patterned gate insulating layer 340a may be silicon oxide or other insulating materials. The gate 350 is disposed on the patterned gate insulating layer 340a above the polysilicon island 330, and a thickness of the gate 350 may range from 100 nm to 3000 nm. Besides, as the gate oxidation layer 360 is formed by performing the anode oxidation process, a material of the gate 350 may be aluminum, tantalum, titanium, or an alloy thereof. In an alternative, when the gate oxidation layer 360 is formed by implementing the thermal oxidation process, a material of the gate 350 may be cooper, aluminum, chromium, molybdenum, tantalum, titanium, or an alloy thereof.

The gate oxidation layer 360 is disposed on the patterned gate insulating layer 340a and covers the gate 350. A thickness of the gate oxidation layer 360 ranges from 100 nm to 1000 nm, preferably in a range between 400 nm and 600 nm. The LDD regions 336a, 336b and the source and drain 332a, 332b are both disposed in the polysilicon island 330. Here, the LDD regions 336a, 336b are disposed in the polysilicon island 330 below two sides of the gate 350, and the polysilicon island 330 disposed right below the gate 350 is a channel region 334. The source and drain 332a, 332b are disposed in the polysilicon island 330 below two sides of the gate oxidation layer 360, and the LDD regions 336a, 336b are located between the source/drain 332a/332b and the channel region 334. Moreover, the patterned gate insulating layer 340a exposes a portion of the source and the drain 332a, 332b.

Specifically, since the LDD regions 336a, 336b 336 are formed by performing the ion implantation process with use of the gate 350 as a mask, an edge of the LDD regions 336a, 336b is aligned to an edge of the gate 350. Alternatively, pattern of the LDD regions 336a, 336b and pattern of the gate 350 are complementary. Besides, since the source and drain 332a, 332b are formed by performing the ion implantation process with use of the gate oxidation layer 360 as the mask, an edge of the source and drain 332a, 332b is aligned to an edge of the gate oxidation layer 360. Alternatively, pattern of the source and drain 332a, 332b and pattern of the gate oxidation layer 360 are complementary. In other words, the LDD regions 336a, 336b are located below the gate oxidation layer 360, and the edge of the gate oxidation layer 360 is aligned to the edge of the LDD regions 336a, 336b.

Referring to FIG. 2F, the patterned dielectric layer 370a is disposed on the patterned gate insulating layer 340a and exposes the source and drain 332a, 332b exposed by the patterned gate insulating layer 340a. In addition, a material of the patterned dielectric layer 370a may be silicon oxide, silicon nitride, or other insulating materials. The source and the drain conductive layers 380a, 380b are disposed on the patterned dielectric layer 370a. Here, the source and the drain conductive layers 380a, 380b are electrically connected to the source and the drain 332a, 332b, respectively. A material of the source and the drain conductive layers 380a, 380b may be chromium or other metallic materials.

In view of the above, the TFT and the manufacturing method thereof according to the present invention have at least the following advantages:

Compared with the conventional manufacturing method requiring two photo masks, the manufacturing method of the TFT according to the present invention employs the gate and the gate oxidation layer formed by the metal oxidation process as the mask for performing the ion implantation process, so as to form the source, the drain and the LDD regions. Thus, only one photo mask is necessary in the manufacturing method of the TFT provided by the present invention.

According to the conventional manufacturing method, symmetrical LDD regions may not be formed due to alignment errors arising among the photo masks. By contrast, in the present invention, the ion implantation process is performed with use of the gate oxidation layer as the mask, and thus the LDD regions at respective sides of the channel region are relatively symmetrical.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A manufacturing method of a thin film transistor (TFT), comprising:
forming a polysilicon island on a substrate;
forming a gate insulating layer on the substrate and covering the polysilicon island;
forming a gate on the gate insulating layer on the polysolicon island;
performing a lightly doped ion implantation process for forming lightly doped drain (LDD) regions in the polysilicon island below two sides of the gate, the polysilicon island right below the gate being a channel region;
performing a metal oxidation process to form a gate oxidation layer on the gate;
performing an ion implantation process to form a source and a drain in the polysilicon island below the two sides of the gate oxidation layer, wherein the LDD regions are located between the source and drain and the channel region;
forming a dielectric layer on the gate insulating layer to cover the gate oxidation layer;
removing a portion of the dielectric layer and a portion of the gate insulating layer to expose a portion of the source and drain and forming a patterned dielectric layer and a patterned gate insulating layer; and
forming a source conductive layer and a drain conductive layer on the patterned dielectric layer, wherein the source and the drain conductive layers are electrically connected to the source and the drain, respectively.

2. The manufacturing method of claim 1, wherein the metal oxidation process comprises an anode oxidation process.

3. The manufacturing method of claim 2, wherein a voltage applied in the anode oxidation process ranges from 5 volts to 200 volts.

4. The manufacturing method of claim 3, wherein a time period of applying the voltage ranges from 10 minutes to 120 minutes.

5. The manufacturing method of claim 2, wherein a material of the gate comprises aluminum, tantalum, titanium, or an alloy thereof.

6. The manufacturing method of claim 1, wherein the metal oxidation process comprises a thermal oxidation process.

7. The manufacturing method of claim 6, wherein a temperature of the thermal oxidation process ranges from 350° C. to 550° C.

8. The manufacturing method of claim 6, wherein a time period of the thermal oxidation process ranges from 2 hours to 24 hours.

9. The manufacturing method of claim 6, wherein a material of the gate comprises copper, aluminum, chromium, molybdenum, tantalum, titanium, or an alloy thereof.

10. The manufacturing method according to claim 1, further comprising forming a buffer layer on the substrate before the polysilicon island is formed.

11. A TFT, comprising:
a substrate;
a polysilicon island, disposed on the substrate;
a patterned gate insulating layer, disposed on the substrate and exposing a portion of the polysilicon island;
a gate, disposed on the patterned gate insulating layer on the polysilicon island;
a gate oxidation layer, disposed on the patterned gate insulating layer and covering the gate;
LDD regions, disposed in the polysilicon island below two sides of the gate, the polysilicon island disposed right below the gate being a channel region;
a source and a drain, disposed in the polysilicon island below two sides of the gate oxidation layer, wherein the patterned gate insulating layer exposes a portion of the source and the drain, and the LDD regions are located between the source/drain and the channel region;
a patterned dielectric layer, disposed on the patterned gate insulating layer and exposing the source and drain exposed by the patterned gate insulating layer; and
a source conductive layer and a drain conductive layer, disposed on the patterned dielectric layer, wherein the source and the drain conductive layers are electrically connected to the source and the drain, respectively.

12. The TFT of claim 11, wherein the LDD regions are located below the gate oxidation layer, and an edge of the gate oxidation layer is aligned to an edge of the LDD regions.

13. The TFT of claim 11, wherein a thickness of the gate oxidation layer ranges from 100 nm to 1000 nm.

14. The TFT of claim 13, wherein the thickness of the gate oxidation layer ranges from 400 nm to 600 nm.

15. The TFT of claim 11, wherein a thickness of the gate ranges from 100 nm to 3000 nm.

16. The TFT of claim 11, wherein a material of the gate comprises copper, aluminum, chromium, molybdenum, tantalum, titanium, or an alloy thereof.

17. The TFT of claim 11, further comprising a buffer layer disposed between the polysilicon island and the substrate.
